(19) United States
(12) Patent Application Publication
(10) Pub. No.: US 2004/0251552 A1
(43) Pub. Date: Dec. 16, 2004

(54) Semiconductor device and manufacturing method the same

(75) Inventors: Toshiyuki Takewaki, Tokyo (JP); Hiroyuki Kunishima, Tokyo (JP); Noriaki Oda, Tokyo (JP)

Correspondence Address: MCGINN & GIBB, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 10/835,459

(22) Filed: Apr. 30, 2004

(30) Foreign Application Priority Data
May 13, 2003 (JP) 135051/2003

(51) Int. Cl. H01L 23/48

(52) U.S. Cl. 257/758

(57) ABSTRACT

A semiconductor device includes a lower layer formed on a substrate and a first insulating layer formed to cover the lower layer. A first concave section is formed to extend from a surface of the first insulating layer to the lower layer. A first taper section is formed along a corner portion between a bottom of the first concave section and an inner wall of the first concave section, and has a taper surface which extends toward a center of the bottom. A first conductor section is formed of material containing copper to fill the first concave section in which the first taper section is formed.

### BACKGROUND OF THE INVENTION

1. Field of the Invention

The present invention relates to a semiconductor device and a method of manufacturing the same, and more particularly to a semiconductor device which uses a metal film containing copper as a wiring line and a contact plug, and a manufacturing method of the same.

2. Description of the Related Art

In a semiconductor device, when a metal film containing copper is used for a wiring line, a damascene method is generally used. In the single damascene method of the damascene method, a lower layer wiring line, a via-plug, an upper layer wiring line are separately formed. A tungsten film is often used for the via-plug. However, the metal containing copper has been used for the via-plug with the miniaturization of the wiring line and the via-plug. A conventional manufacturing method of the single damascene structure using copper for the via-plug is disclosed in Japanese Laid Open Patent Application (JP-P2002-289689A).

FIGS. 1A to 1L are cross sectional views showing the conventional manufacturing method of the wiring line and the via-plug which have the single damascene structure. In this example, wiring lines are provided for two layers and a via-plug is formed to connect them.

As shown in FIG. 1A, a stopper insulating layer 102 is formed on an interlayer insulating film 101 which is formed on a substrate 140, and a first wiring layer 106 is formed in a low dielectric constant insulating layer 103. The first wiring layer 106 has a damascene structure which contains a wiring line 129 of copper (Cu) and a barrier metal layer 128 of tantalum/tantalum nitride (Ta/TaN). The damascene structure is formed by using a conventionally known wiring line manufacture process. A stopper insulating film 104 is formed to cover the wiring line 106 and the low dielectric constant insulating layer 103. Subsequently, an interlayer insulating film 105 is formed to cover the stopper insulating film 104.

Next, as shown in FIG. 1B, by using the process of a photo lithography, a via-hole 107 is formed to pass through the stopper insulating film 104 and the interlayer insulating film 105. In this case, the via-hole 107 is washed with organic peeling liquid and rinsed with non-aqueous solution (for example, isopropyl alcohol).

Next, as shown in FIG. 1C, a barrier metal film 108 of Ta/TaN is formed by a sputtering method, to cover the interlayer insulating layer 105 and an inner wall and bottom of the via-hole 107. Thus, the via-hole 107 becomes a via-hole 107a at this time.

Next, as shown in FIG. 1D, a seed conductor film 109a of Cu is formed to cover the barrier metal film 108. Thus, a via-hole 107b is formed at this time.

Next, as shown in FIG. 1E, a conductor film 109b of Cu is formed to cover the seed conductor film 109a and to fill the via-hole 107. Then, as shown in FIG. 1F, an unnecessary barrier metal film 108, the seed conductor film 109a and the conductor film 109b on the interlayer insulating layer 105 and above the via-hole 107 are removed by a CMP (Chemical Mechanical Polishing) method. In this way, a via-plug 132 (or a contact) of the barrier metal layer 108 and a conductor section 109 (109a and 109b) is formed.

Next, as shown in FIG. 1G, a stopper insulating film 112 is formed to cover the via-plug 132 and the interlayer insulating film 105. Moreover, a low dielectric constant insulating film 113 is formed to cover the stopper insulating film 112.

Next, as shown in FIG. 1H, by using the photo lithography process, a wiring line trench 117 is formed to pass through the stopper insulating film 112 and the low dielectric constant insulating film 113.

Next, as shown in FIG. 1I, a barrier metal film 118 of Ta/TaN is formed by the sputtering method to cover the low dielectric constant insulating layer 113 and an inner wall and bottom of the wiring line trench 117.

Next, as shown in FIG. 1J, a seed conductor film 119a of Cu is formed to cover the barrier metal film 118.

Next, as shown in FIG. 1K, a conductor film 119b of Cu is formed to cover the seed conductor film 119a and to fill the wiring line trench 117.

Next, as shown in FIG. 1L, an unnecessary barrier metal film 118, the seed conductor film 119a and the conductor film 119b on the low dielectric constant insulating layer 113 and above the wiring line trench 117 are removed by the CMP method.

In this way, the wiring line 133 of the barrier metal layer 118 and the conductor layer 119 is formed.

In addition to the above description, a semiconductor integrated circuit device which is explained later is disclosed in Japanese Laid Open Patent Application (JP-P2002-289689A). The semiconductor integrated circuit device of this conventional example has a semiconductor substrate, a first insulating layer, a first conductive layer, a first upper side conductive barrier layer, a second insulating layer, a second conductive layer and a second upper side conductive barrier layer. A plurality of semiconductor devices are formed the semiconductor substrate. The first insulating layer is formed on the semiconductor substrate. The first conductive layer is embedded in the first insulating layer. The semiconductor device also contains a first wiring layer, a first pad layer, a first wiring layer, and a first humidity-proof ring layer arranged to surround the outside of the first pad layer. A first upper side conductive barrier layer extends to the first insulating layer from the surface of each of the first pad layer and the first humidity-proof ring layer in the first conductive layer. The second insulating layer is formed on the first insulating layer to cover the first upper side conductive barrier layer. The second conductive layer is formed to be embedded in the second insulating layer. The second conductive layer contains a second wiring layer which reaches the first wiring layer and the second pad layer, and the second humidity-proof ring layer which reaches the first upper side conductive barrier layer. The second upper side conductive barrier layer extends to the second insulating layer from the surface of each of the second pad layer and the second humidity-proof ring layers in the second conductive layer.

The semiconductor integrated circuit device of this conventional example has a purpose of preventing the pad section from peering and minimizing damage to the lower layer wiring line in the etching to the via-hole and the humidity-proof ring trench.

Also, a semiconductor device is disclosed in Japanese Laid Open Patent Application (JP-P2000-332103A). The semiconductor device of this conventional example is composed of a semiconductor substrate, a first wiring layer, an interlayer insulating film and a through-hole. The semiconductor device is further composed of a gap filling member, a barrier metal film and a second wiring layer. The first wiring layer is provided on the semiconductor substrate and has a reflection prevention film on it. The interlayer insulating film is provided on the semiconductor substrate to cover the first wiring layer. The through-hole passes through the interlayer insulating film and the reflection prevention film to expose a part of the surface of the first wiring layer. In the through-hole, the tails of the reflection prevention film extend in a horizontal direction. The gap filling member fills a crack portion under the tails. The surface of the exposed surface of the first wiring layer, the wall surface of the through-hole and the interlayer insulating film are continuously covered by the barrier metal film. A second wiring layer is provided on the interlayer insulating film to connect with the first wiring layer through the barrier metal film and the through-hole. The gap filling member may be material obtained by sputtering etching the surface of the semiconductor the substrate.

Specifically, in this conventional semiconductor device, a gap between the aluminum wiring line and the reflection prevention film is filled with the gap filling material in the through-hole provided to connect the aluminum wiring lines in the two different layers. A purpose of this conventional technique is to provide the semiconductor device, in which the wiring line in the upper layer is prevented from being broken in the through-hole.

In recent years, the miniaturization of a semiconductor device is increasingly moving ahead. Therefore, the aspect ratio of a wiring line and a via-plug tends to become large. FIG. 2A shows a situation when the aspect ratio of the via-plug 132 becomes large in the wiring lines 106 and 133 and the via-plug 132 of the single damascene structure of FIG. 1L. It is difficult to from the barrier metal film 108 in the corner portions 120 where the side walls and the bottom intersect, when the aspect ratio of the via-hole 107 is large. This is because the barrier metal film 108 is difficult to reach the corner portions 120. When the barrier metal film 108 is not formed, copper (Cu) of the seed conductor film 109a directly contacts the stopper insulating layer 104 and the interlayer insulating layer 105 of silicon oxide. The film of copper in the contact portion is not good in the film quality, and tends to contain a lot of amorphous portions. Especially, this is conspicuous in case that the copper film contacts the interlayer insulating layer 105. One of the causes is in the point that remaining moisture and the peeling liquid are left in the interlayer insulating layer 105 in the washing process after the via-hole 107 is formed.

Also, as shown in FIG. 2B, copper formed directly on the insulating film causes aggregation due to heat stress generated by a high temperature process such as a forming process of the interlayer insulating film as a post process. That is, Cu in the conductor via-plug 132 moves around and becomes conductors 126 with a globular shape in a thermally stable state. Spaces 125 are produced in the via-plug 132 and the via-plug 132 becomes electrically non-conductive. Such non-conductiveness is also caused in the wiring line with a large aspect ratio because of the similar generation process in addition to the via-plug 132.

### SUMMARY OF THE INVENTION

Therefore, an object of the present invention is to provide a semiconductor device improved in the reliability of a wiring line containing a contact and a method of manufacturing the semiconductor device.

Another object of the present invention is to provide a semiconductor device in which a wiring line containing a contact can be prevented from being broken and a method of manufacturing the semiconductor device.

Another object of the present invention is to provide a semiconductor device in which the migration of copper (Cu) of a wiring line containing a contact can be prevented and a method of manufacturing the semiconductor device.

Another object of the present invention is to provide a semiconductor device in which it is possible to surely form a barrier metal film of a wiring line containing a contact and a method of manufacturing the semiconductor device.

In an aspect of the present invention, a semiconductor device includes a lower layer formed on a substrate and a first insulating layer formed covering the lower layer. A first concave section extends from a surface of the first insulating layer to the lower layer. A first taper section is formed along a corner portion between a bottom of the first concave section and an inner wall of the first concave section, and has a taper surface which extends toward a center of the bottom. A first conductor section is formed of material containing copper to fill the first concave section in which the first taper section is formed.

Here, the lower layer may include an interlayer insulating film formed on the substrate, a second insulating layer formed on the interlayer insulating film, and a second conductor section formed of material containing copper in the second insulating layer at a position corresponding to the first conductor section.

The lower layer may further include a second taper section formed along a corner portion between a bottom of a first trench and each of side walls of the first trench. The first trench may extend from a surface of the second insulating layer to the interlayer insulating film, and the second conductor section may be provided to fill the first trench.

In this case, the second taper section may be formed of substantively same material as the interlayer insulating film, and the second conductor section may extend to an inside of the interlayer insulating film.

Also, the semiconductor device may further include a third insulating layer formed on the first insulating layer and the first conductor section, and a third conductor section formed of material containing copper in the third insulating layer at a region including a position corresponding to the first conductor section. In this case, the semiconductor device may further include a third taper section formed along a corner portion between a bottom of a second trench and each of side walls of the second trench. The second trench extends from a surface of the third insulating layer to the first conductor section, and the third conductor section is formed by filling the second trench.

Also, the third taper section may be formed of substantively same material as the first conductor section, and the third conductor section may extend to an inside of the first conductor section.

Also, the second and third conductor sections are first and second wiring lines, respectively, and the first conductor section is as a contact plug to connect the first and second wiring lines.

Also, an aspect ratio of the first concave section is equal to or more than 2.

In another aspect of the present invention, a method of manufacturing a semiconductor device is achieved by (a) forming a first concave section extending from a surface of a first insulating layer to a lower layer such that a part of a surface of the lower layer is exposed, wherein the first insulating layer is formed on the lower layer which is formed on a substrate; by (b) forming a first taper section along a corner portion between a bottom of the first concave section and an inner wall of the first concave section; and by (c) forming a first conductor section of metal containing copper by filling the first concave section in which the first taper section is formed.

Here, in the (b) forming, sputter-etching may be carried out to a bottom of the first concave section such that etched material of the lower layer is deposited in the corner portion to produce the first taper section.

Also, in the (b) forming, an auxiliary film may be formed to cover the inner wall and the bottom of the first concave section, and a surface of the first insulating layer; and etching back may be carried out to the auxiliary film to produce the first taper section and to remove the auxiliary film from the inner wall and the bottom of the first concave section, and the surface of the first insulating layer.

Here, the lower layer contains a second conductor section of material containing copper, and the (a) forming may include exposing a part of the second conductor section in the first concave section.

Also, in the manufacturing method of the semiconductor device, the lower layer may be formed by forming an interlayer insulating film on the substrate; by forming a second insulating layer on the interlayer insulating film; and by forming a second conductor section of material containing copper in the second insulating layer at a region including a position corresponding to the first conductor section. In this case, the forming the lower layer may be further achieved by forming a first trench in the second insulating layer to extend from a surface of the second insulating layer to the interlayer insulating film; by forming a second taper section along a corner portion between a bottom of the first trench and each of side walls of the first trench; and by filling the first trench with the second conductor section. In this case, the second taper section is formed of substantively same material as the interlayer insulating film.

Also, in the manufacturing method of the semiconductor device, an upper layer may be achieved by forming a third insulating layer on the first insulating layer and the first conductor section; by forming a second trench in the third insulating layer to extend from a surface of the third insulating layer to the first conductor section; by forming a third taper section along a corner portion between a bottom of the second trench and each of side walls of the second trench; and by forming a third conductor section of material containing copper by filling the second trench. In this case, the forming the third taper section includes forming the third taper section with substantively same material as the first conductor section.

Also, the second and third conductor sections are first and second wiring lines, respectively, and the first conductor section is as a contact plug to connect the first and second wiring lines.

Also, an aspect ratio of the first concave section may be equal to or more than 2.

### BRIEF DESCRIPTION OF THE DRAWINGS

FIGS. 1A to 1L are cross sectional views showing a conventional method of manufacturing a via-plug and a wiring line of a single damascene structure;

FIGS. 2A and 2B is cross sectional views showing via-plugs of a single damascene structure in a large aspect ratio;

FIG. 3 is a cross sectional view showing the structure of a semiconductor device according to an embodiment of the present invention;

FIG. 4 is a perspective view showing a part of wiring lines and a via-plug in two layers of the semiconductor device in the embodiment;

FIG. 5A is a perspective view showing a cross section of the wiring line containing a taper section, and FIG. 5B is a perspective view showing a cross section on the via-hole containing the taper section;

FIGS. 6A to 6R are cross sectional views showing the structure of the semiconductor device according to the embodiment of the present invention in manufacturing processes; and

FIGS. 7A and 7B are cross sectional views showing another method for forming a taper section;

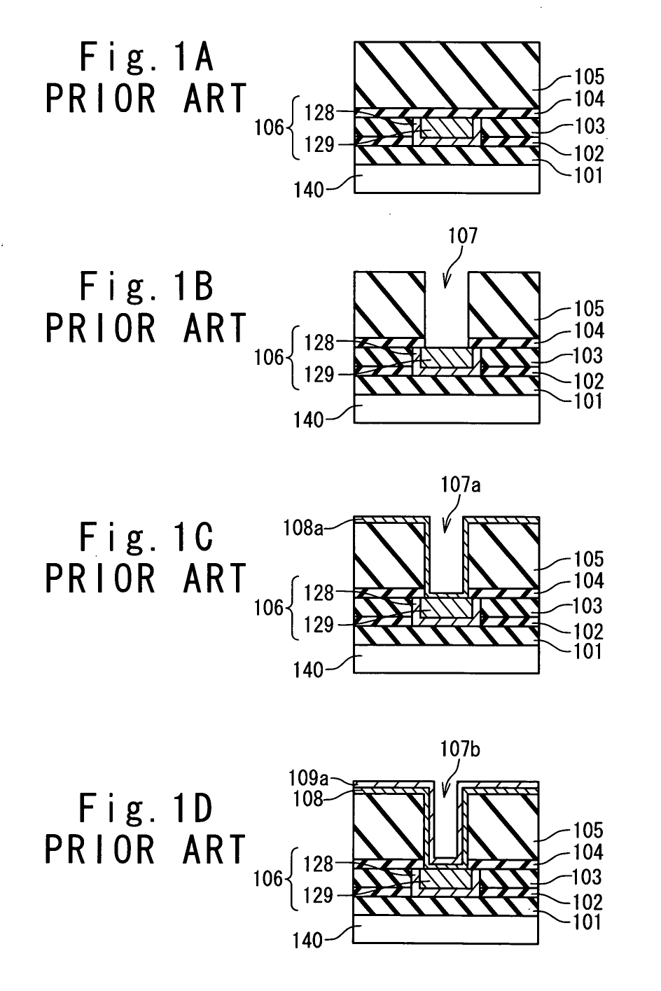

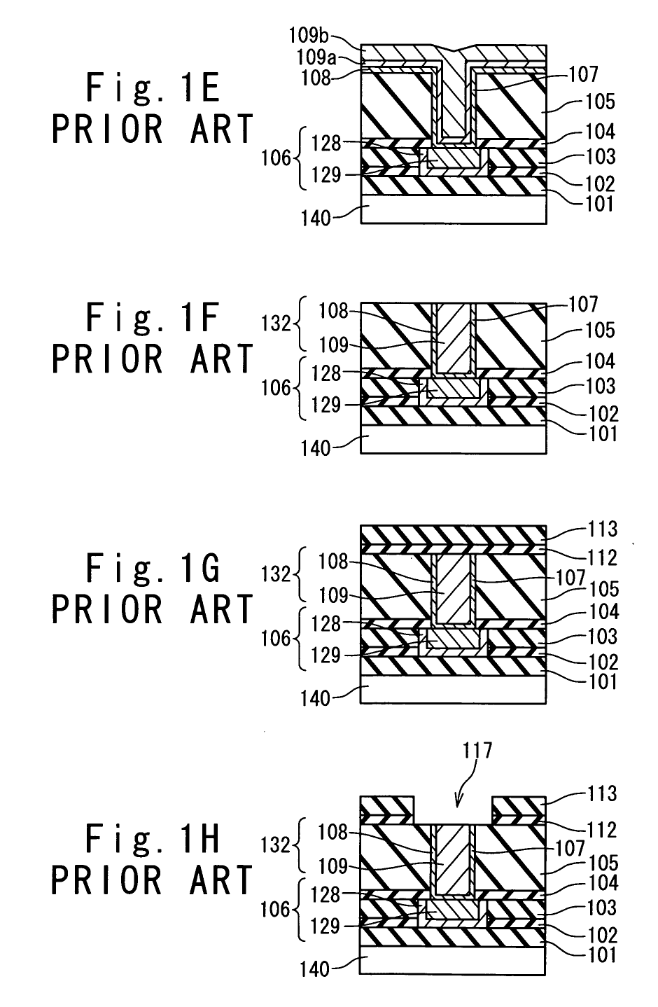

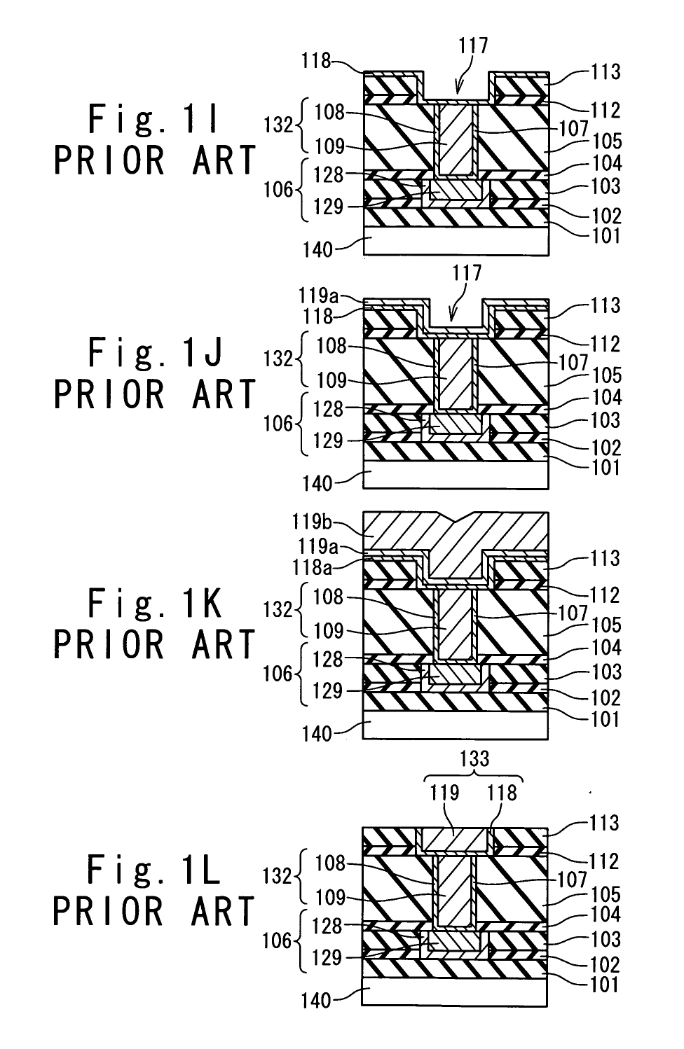

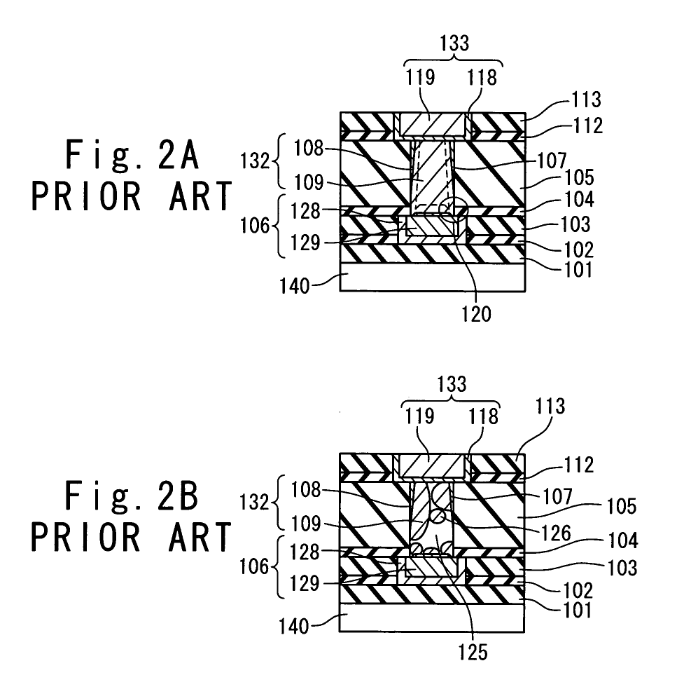

### DESCRIPTION OF THE PREFERRED EMBODIMENTS

Hereinafter, a semiconductor device and a manufacturing method for the same of the present invention will be described with reference to the attached drawings.

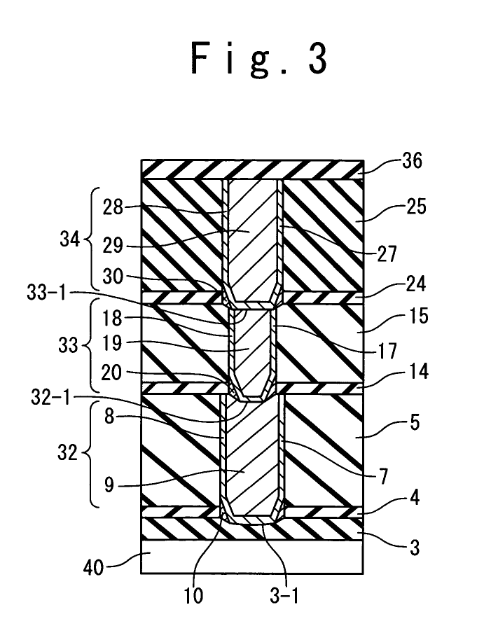

FIG. 3 is a cross sectional view showing the structure of the semiconductor device according to the embodiment of the present invention. Referring to FIG. 3, the semiconductor device in the embodiment is provided on a substrate 40, and includes an interlayer insulating layer 3, a stopper insulating layer 4, a low dielectric constant insulating layer 5, and first taper sections 10, a first wiring line 32 containing a barrier metal layer 8 and a conductor section 9, a stopper insulating layer 14, an interlayer insulating layer 15, a via-plug 33 containing a second taper section 20, a barrier metal layer 18 and a conductor section 19, a stopper insulating layer 24, a low dielectric constant insulating layer 25, a third taper sections 30, a second wiring line 34 containing a barrier metal layer 28 and a conductor section 29, and a stopper insulating layer 36.

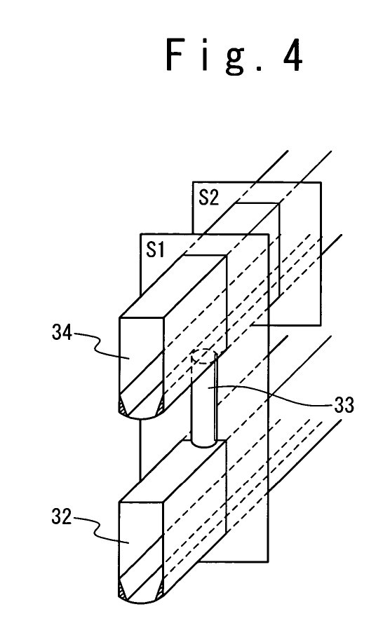

FIG. 4 is a perspective view showing a part of wiring lines and a via-plug in two layers of the semiconductor device. The first wiring line 32 is connected with the second wiring line 34 by the via-plug 33. FIG. 3 shows the cross section of the semiconductor device along a plane S1 in FIG. 4. Also, the cross section of the second wiring line 34 along a plane S2 is the same as the cross section of the first wiring line 32.

Referring to FIG. 3, again, the substrate 40 may be a semiconductor substrate of silicon, or an SOI (Silicon on Insulator) substrate in which an inorganic insulating film of silicon oxide or silicon nitride is formed. Instead, a semiconductor substrate having a multi-layer structure may be used in which a plurality of wiring layers and elements are embedded in an insulating film. In this embodiment, the silicon substrate is used. The interlayer insulating layer 3 is provided to cover the substrate 40.

The interlayer insulating layer 3 is an insulating film formed by a CVD method or a spin coat method. The interlayer insulating layer 3 is formed of organic material to electrically isolate between wiring lines, between the wiring line and a device, and between the devices. The interlayer insulating layer 3 is formed of material of a low dielectric constant to reduce a parasitic capacity of the wiring line. In this embodiment, the interlayer insulating layer 3 is not an inorganic insulating film such as a silicon oxide film (of the relative dielectric constant of 4.2) but a low dielectric constant film of an organic polymer having a low relative dielectric constant equal to or less than 3.0.

The stopper insulating layer 4 is provided to cover the interlayer insulating layer 3. The stopper insulating layer 4 is an insulating film formed on the interlayer insulating film 3 by the CVD method or the spin coat method. The stopper insulating layer 4 protects the interlayer insulating film 3 in a process in which the wiring line trench 7 for a first wiring line 32 is formed by the photo lithography method. The stopper insulating layer 4 is formed of inorganic material such as silicon oxide, silicon nitride, and silicon carbide. Also, the stopper insulating layer 4 may be formed of silicon oxide in which organic ions, organic groups, hydrogen ions, hydroxyl groups are doped as impurity. In this embodiment, the stopper insulating layer 4 is formed of silicon carbide nitride (SiCN). The stopper insulating layer 4 has the film thickness of approximately 50 nm, for example.

The low dielectric constant insulating layer 5 is provided to cover the stopper insulating layer 4. The low dielectric constant insulating layer 5 is an insulating film formed by the CVD method or the spin coat method. The low dielectric constant insulating layer 5 is formed of organic material to electrically isolate between the wiring lines, between the wiring line and the device, and between the devices. The low dielectric constant insulating layer 5 is formed of the material having a low dielectric constant to reduce a parasitic capacity of the wiring line. For example, in this embodiment, like the interlayer insulating film 3, the low dielectric constant insulating layer 5 is formed as a low dielectric constant film of an organic polymer which has a low relative dielectric constant equal to or less than 3.0. The low dielectric constant insulating layer 5 has the film thickness approximately 300 nm, for example.

The wiring line trench 7 is provided to pass through the low dielectric constant insulating layer 5 and the stopper insulating layer 4 to the interlayer insulating layer 23 from the surface of the low dielectric constant insulating layer 5. The first wiring line 32 is formed in the wiring line trench 7. The bottom of the wiring line trench 7 corresponds to a contact section 3-1 as a part of the upper portion of the interlayer insulating layer 3.

The first taper sections 10 are formed in corner portions where the side walls of the wiring line trench 7 and the bottom thereof (i.e., the contact section 3-1) intersect. The first taper section 10 has a taper surface toward the center of the bottom. The first taper section 10 fills the above-mentioned corner portion and improves the shape of the corner portion where the barrier metal layer 8 is difficult to be formed. It is desirable to apply the first taper sections 10 to the wiring line trench 7 with a large aspect ratio (i.e., wiring line depth/wiring line width). The reason is in that when the aspect ratio is larger, for example, is equal to or larger than 2, it is more difficult to form the barrier metal layer 8 in the bottom corner portions in the wiring line trench 7. The first taper sections 10 are formed when the upper portion of the interlayer insulating layer 3 is etched. That is, the material sputtered from the upper portion of the interlayer insulating layer 3 adheres to the corner portions to form the first taper sections 10, by appropriately controlling a condition of the sputtering etching. Therefore, the first taper section 10 is formed of the same material as the interlayer insulating layer 3. In this case, the volume of the first taper sections 10 is substantially equal to the volume of the part sputtered from the interlayer insulating layer 3, and the cross section of the first wiring line 32 changes hardly. Therefore, without changing the design of the wiring line, the first taper sections 10 can be formed.

The first wiring line 32 is provided to fill the wiring line trench 7. The first wiring line 32 contains the barrier metal layer 8 and the conductor section 9. For example, the size of the first wiring line 32 has the width of 220 nm and the depth of 450 nm.

The barrier metal layer 8 is formed to cover the side walls and the bottom of the wiring line trench 7, containing the taper surfaces of the first taper sections 10. The barrier metal layer 8 is formed from a metal film by the sputtering method. The barrier metal layer 8 prevents the conductor section 9 from diffusing into the interlayer insulating layer 5 and the conductor section 9 from aggregating. The barrier metal layer 8 is formed of high melting point metal (refractory metal) or nitride of it. For example, the barrier metal layer 8 is formed of tantalum, tantalum nitride, titanium nitride or a lamination film of some of them. In this embodiment, the barrier metal layer 8 is a lamination film of tantalum/tantalum nitride (Ta/TaN). For example, the barrier metal layer 8 has the film thickness approximately 30 nm.

The conductor section 9 is formed to fill the wiring line trench 7 in which the barrier metal layer 8 has been formed. The conductor section 9 is a metal film formed by the sputtering method or a plating method. The conductor section 9 is formed of metal with a low resistivity. For example, the conductor section 9 is formed of metal containing copper such as copper and copper-aluminum. In this embodiment, copper (Cu) is used.

The stopper insulating layer 14 is formed to cover the low dielectric constant insulating layer 5 and the first wiring line 32. The material, manufacturing method and film thickness of the stopper insulating layer 14 are the same as those of the stopper insulating layer 4.

Also, the interlayer insulating layer 15 is formed to cover the stopper insulating layer 14. The material and manufacturing method of the interlayer insulating layer 15 are the same as those of the interlayer insulating layer 3. For example, the interlayer insulating layer 15 has the film thickness approximately 400 nm.

The via-hole 17 is formed to pass through the interlayer insulating layer 15 and the stopper insulating layer 14 to the first wiring line 32 from the surface of the interlayer insulating layer 15. The via-plug 33 is formed in the via-hole 17. The bottom of the via-hole 17 corresponds to the connection portion 32-1 as a part of the upper portion of the first wiring line 32.

The second taper section 20 is formed in corner portion where the inner wall and the bottom (connection portion 32-1) intersect in the via-hole 17. The second taper section 20 has a taper surface toward the center of the bottom. The second taper section 20 fills the above-mentioned corner portion and improves the shape of the corner portions where it is difficult to form the barrier metal layer 18.

The via-plug 33 is formed from the barrier metal layer 18 and the conductor section 19 by using the second taper section 20. It is desirable to apply the second taper section 20 to the via-hole 17 with a large aspect ratio. The reason is in that when the aspect ratio is larger, e.g., the aspect ratio is equal to or larger than 2.0, it is more difficult to form the barrier metal layer 18 in the corner portions of the via-hole 17. The second taper section 20 is formed by etching the upper portion of the first wiring line 32 by the sputtering method. That is, the material sputtered from the upper portion of the first wiring line 32 adheres to the corner portion of the via-hole 17 to form the second taper section 20, by appropriately controlling the condition of the sputtering etching. Therefore, the second taper section 20 is formed of the same material as the first wiring line 32 and is metal containing copper. The temperature of the sputtering etching is desirably low to the extent that the temperature in the portion where the second taper section 20 is formed does not cause aggregation of copper (Cu). For this purpose, it is desirable to keep the substrate 40 at the room temperature or below. Because the second taper section 20 is formed of the metal containing copper, the resistance value of the via-plug 33 changes hardly. That is, without changing the design of the wiring line almost, the second taper section 20 can be formed.

The via-plug 33 is formed to fill the via-hole 17. The via-plug 33 contains the barrier metal layer 18, the conductor section 19 and the second taper section 20. For example, the size of the via-plug 33 has the width of 200 nm and the depth of 450 nm.

The barrier metal layer 18 is formed to cover the side walls and a bottom of the via-hole 17, containing the taper surface of the second taper section 20. The barrier metal layer 18 is formed by the sputtering method, and prevents the conductor section 19 from diffusing into the interlayer insulating layer 15 and the conductor section 19 from aggregating. The barrier metal layer 18 is formed of high melting point metal (oxidation resistant metal) or nitride. For example, the barrier metal layer 18 is tantalum and tantalum nitride, titanium nitride, and a lamination film of some of them. In this embodiment, the barrier metal layer 18 is formed as a lamination film of tantalum/tantalum nitride (Ta/TaN). For example, the barrier metal layer 18 has the film thickness of approximately 30 nm. The film forming temperature is desirably low to the extent that copper (Cu) contained in the second taper section 20 does not aggregate. Therefore, it is desirable to keep the substrate 40 at the room temperature or below.

The conductor section 19 is formed to fill the via-hole 17 in which the barrier metal layer 18 has been formed. The conductor section 19 is formed by the sputtering method or the plating method. The conductor section 19 is formed of metal with low resistivity. For example, the conductor section 19 is copper containing metal such as copper and copper-aluminum. In this embodiment, copper (Cu) is used.

The stopper insulating layer 24 is formed to cover the interlayer insulating layer 15. The material, manufacturing method and film thickness are the same as those of the stopper insulating layer 4.

The low dielectric constant insulating layer 25 is formed to cover the stopper insulating film 24. The material, manufacturing method and film thickness are the same as those of the low dielectric constant insulating layer 5.

The wiring line trench 27 is formed to pass through the interlayer insulating layer 15 to the via-plug 33 from the surface of the low dielectric constant insulating layer 25. The second wiring line 34 is formed in the wiring line trench 27. The bottom of the wiring line trench 27 corresponds to the joint portion 33-1 as a part of the upper portion of the via-plug 33.

The third taper sections 30 are formed in the corner portions where the side walls of the wiring line trench 27 and the bottom thereof (i.e., contact portion 33-1) intersect in the wiring line trench 27. The third taper section 30 has a taper surface toward the center of the bottom. The third taper section 30 fills the above-mentioned corner portion and improves the shape of the corner portion where it is difficult to form the barrier metal layer 28. The third taper sections 30 are formed by etching the upper portions of the via-plug 33 and the interlayer insulating layer 15 (but mainly the via-plug 33). That is, the material sputtered from the upper portion of the via-plug 33 and the interlayer insulating layer 15 adheres to the corner portions to form the third taper sections 30, by appropriately controlling the condition of the sputtering etching. Therefore, the main component of the material of the third taper section 30 is substantially the same copper containing metal as the via-plug 33 and sometimes contains the same insulator as the interlayer insulating layer 15 partially. Also, the main component contains the same insulator as the interlayer insulating layer 15 on the interlayer insulating layer 15. It is desirable to apply the third taper sections 30 to the wiring line trench 27 with a large aspect ratio (wiring line depth/wiring line width). When the aspect ratio is large, it becomes difficult to form the barrier metal layer 28 in the corner portions of the wiring line trench 27. The aspect ratio at that time is equal to or larger than 2.0. The temperature of the sputtering etching is desirably low to the extent that copper (Cu) does not aggregate in the corner portions where the third taper sections 30 are formed. It is desirable to keep the substrate 40 at the room temperature or below. In this case, because the resistivity of the third taper section 30 on the via-plug 33 is substantially equal to the resistivity of the metal of the via-plug 33, the cross section of the first wiring line 32 changes hardly. Also, because the volume of the insulator sputtered from the interlayer insulating layer 15 is substantially the same as the volume of the third taper sections 30, the cross section of the second wiring line 34 changes hardly. Therefore, without changing the design of the wiring line almost, the third taper sections 30 can be formed.

The second wiring line 34 is formed to fill the wiring line trench 27. The second wiring line 34 contains the barrier metal layer 28 and the conductor section 29. For example, the size of the second wiring line 34 has the width of 220 nm and the depth of 450 nm.

The barrier metal layer 28 is formed to cover the side walls and bottom of the wiring line trench 7, containing the taper surfaces of the third taper sections 30. The material, manufacturing method and film thickness are the same as those of the barrier metal layer 8. However, the film forming temperature is desirable low to the extent that copper (Cu) contained in the third taper section 30 does not aggregate. Therefore, it is desirable to keep the substrate 40 at the room temperature or below.

The conductor section 29 is formed to fill the wiring line trench 27 where the barrier metal layer 28 has been formed. The material and manufacturing method are the same as those of the conductor section 9.

The stopper insulating layer 36 is formed to cover the low dielectric constant insulating layer 25 and the second wiring line 34. The material, manufacturing method and film thickness are the same as those of the stopper insulating layer 4.

Next, the first to third taper sections 10, 20 and 30 will be described.

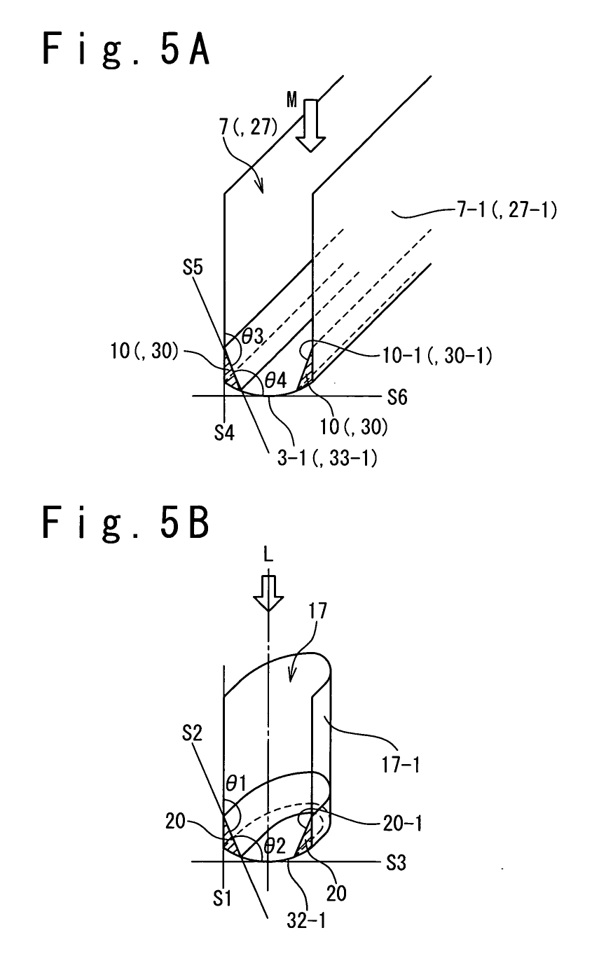

FIG. 5A is a perspective view showing the cross section of the wiring line trench 7 containing the first taper section 10 or the wiring line trench 27 containing the third taper section 30. The axis M shows a direction perpendicular to the substrate 40. Because the structure of the first taper sections 10 and that of the third taper sections 30 are the same, only the first taper sections 10 will be described.

The first taper sections 10 are formed along the corner portions in the side walls 7-1 of the wiring line trench 7 and the contact section 3-1 as the bottom. The first taper section 10 has the taper surface 10-1 toward the center of the bottom. It is possible to eliminate the sharp corner portions of the wiring line trench 7 by this taper surface 10-1.

The plane formed from the taper surface 10-1 and the surface of the bottom (contact section 3-1) may be smoothly formed in a convex state in a direction shown by the arrow in the figure (i.e., a direction from the low dielectric constant insulating layer 5 to the substrate 40). In this case, because the plane is in a smooth convex state, the portions in the wiring line trench 7 where it is difficult to form the barrier metal layer 8 can be eliminated.

The first taper section 10 may have the following shape. That is, an angle (θ3 in the figure) between an effective plane (S4) of the side wall 7-1 extending in the direction perpendicular to the substrate 40 and an effective plane (S5) of the taper surface 10-1 in the wiring line trench 7 is beyond 90 degrees and less than 180 degrees. At the same time, an angle (θ4) between the effective plane (S5) and an effective surface (S6) of the contact section 3-1 is beyond 90 degrees and less than 180 degrees. In this case, because the angle between the effective planes is gentle, the sharp corner portions where it difficult to form the barrier metal layer 8 in the wiring line trench 7 can be eliminated. Here, each of the effective planes needs not to be a flat plane and may have a curved surface and small unevenness to the extent that the forming of the barrier metal layer 8 is not difficult. That is, the width of the bottom is made narrower by the first taper sections 10 than the distance between the side walls 7-1. In the taper surface 10-1, the distance decreases monotonously from the distance between the side walls 7-1 and becomes equal to the width of the contact section 3-1 in the bottom.

The uniform barrier metal layer 8 can be easily formed in the wiring line trench 7 in the shape determined based on the side walls 7-1, the taper surfaces 10-1 and the bottom of the wiring line trench 7 containing the contact section 3-1. In addition, there is the following effect about the region between a lower portion of the side wall 7-1 and an upper portion above the first taper section 10. The region is referred to as a “film forming difficult region”, hereinafter. In the film forming difficult region, it was conventionally difficult to form the barrier metal layer 8. However, in the present invention, the barrier metal layer 8 is easily formed on the taper surface 10-1 under the film forming difficult region. Also, the barrier metal layer 8 is easily formed in an upper region of the side wall 7-1 than the film forming difficult region. That is, while the barrier metal layer 8 is formed, the film growth proceeds from the upper region and the lower region than the film forming difficult region. Therefore, the barrier metal layer 8 can be surely formed in the film forming difficult region. Thus, it is possible to eliminate the region where it is difficult to from the barrier metal layer 8, in the wiring line trench 7. Also, the barrier metal layer 8 can be surely formed on the whole inside of the wiring line trench 7.

FIG. 5B is a perspective view showing the cross section of the via-hole 17 containing the second taper section 20. The axis L shows a central axis on the via-hole 17 of a column shape. The second taper section 20 is formed along the corner portion between the inner wall 17-1 of the via-hole 17 and the contact section 32-1 as the bottom, and has the taper surface 20-1 toward the center of the bottom. Portions such as the corner portions of the via-hole 17 where it is difficult to form the barrier metal layer 18 can be eliminated by this taper surface 20-1.

The surface formed from the taper surface 20-1 and the bottom (i.e., the contact 32-1) may be smoothly formed in a convex state in a direction of the axis L shown by the arrow in the figure (i.e., in a direction from the interlayer insulating layer 15 to the substrate 40). In this case, since the surface is in the smooth and convex state, it is possible to eliminate a region, where it is difficult to form the barrier metal layer 18, from the via-hole 17.

The second taper section 20 may have the following shape. That is, an angle (θ1) between an effective plane (S1) as the inner circumference plane of the via-hole 17 perpendicular to the substrate 40 and an effective plane (S2) of the taper surface 20-1 in the side wall 17-1 is beyond 90 degrees and less than 180 degrees. At the same time, an angle (θ2) between the effective surface (S2) and an effective plane (S3) of the contact or bottom 32-1 is beyond 90 degrees and less than 180 degrees. In this case, because the angle between the effective planes becomes gentle, the difficulty to form the barrier metal layer 18 in the via-hole 17 can be eliminated. Here, each effective surface needs to be a flat plane and may have a curved surface and small unevenness to the extent that the forming of the barrier metal layer 18 is not difficult. That is, the diameter of the bottom is made narrower for the second taper section 20 than the diameter of the via-hole 17. The diameter decreases monotonously from the diameter of the via-hole 17 at the upper portion of the via-hole 17, and becomes equal to the diameter of the contact section 32-1 in the bottom.

The uniform barrier metal layer 18 can be easily formed in the bottom of the via-hole 17 because of the shape determined based on the inner wall 17-1, the taper surface 20-1 and the bottom of the via-hole 17 containing such a contact section 32-1. In addition, there is the following effect about the film forming difficult region where it is difficult to form the barrier metal layer 18, and which is located between the lower portion of the via-hole and an upper portion than the second taper section 20. First, the barrier metal layer 18 is easily formed on the taper surface 20-1 in the lower region then the film forming difficult region. Also, the barrier metal layer 18 is easily formed on the inner wall 17-1 in the upper region than the film forming difficult region. That is, while the barrier metal layer 18 is formed, the film growth proceeds from the upper and lower region of the film forming difficult region. Therefore, the barrier metal layer 18 can be surely formed in the film forming difficult region. Thus, it is possible to eliminate the region where it is difficult to from the barrier metal layer 18, from the via-hole 17. Also, the barrier metal layer 8 can be surely formed on the whole inside of the via-hole 17.

It should be noted that the via-hole 17 need not be a perfect cylinder shape and may be a prism shape. In this case, the axis L shows a straight line perpendicular to the substrate 40 passing through the center of the bottom.

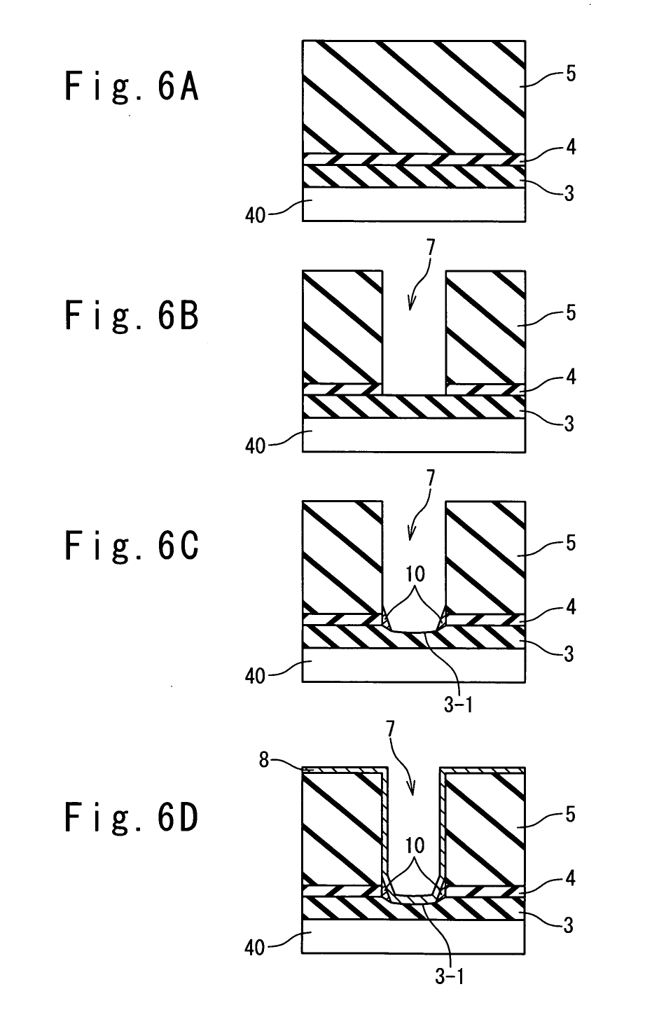

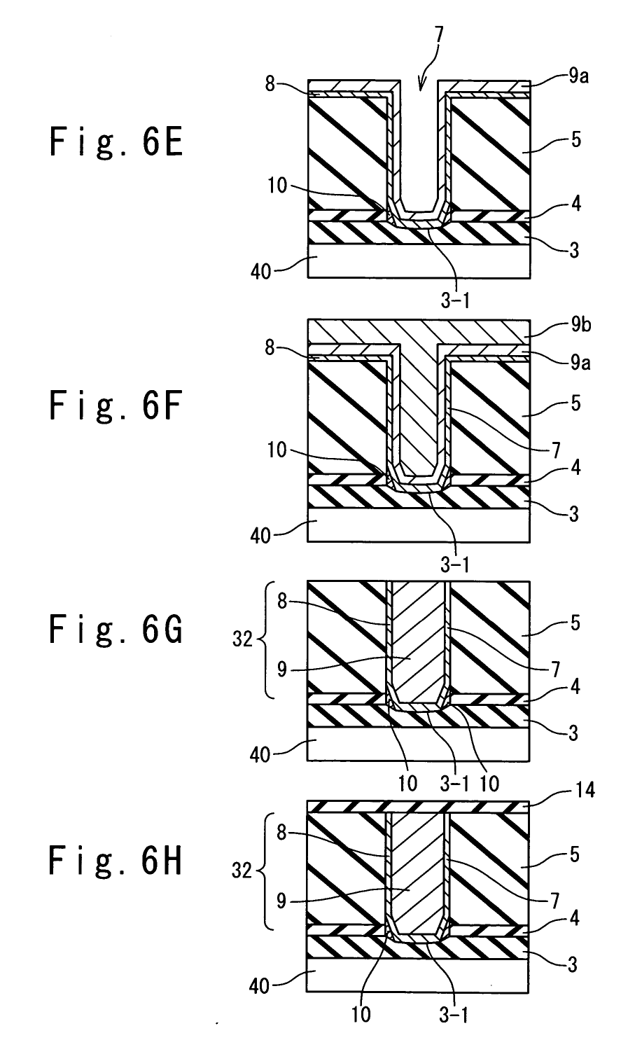

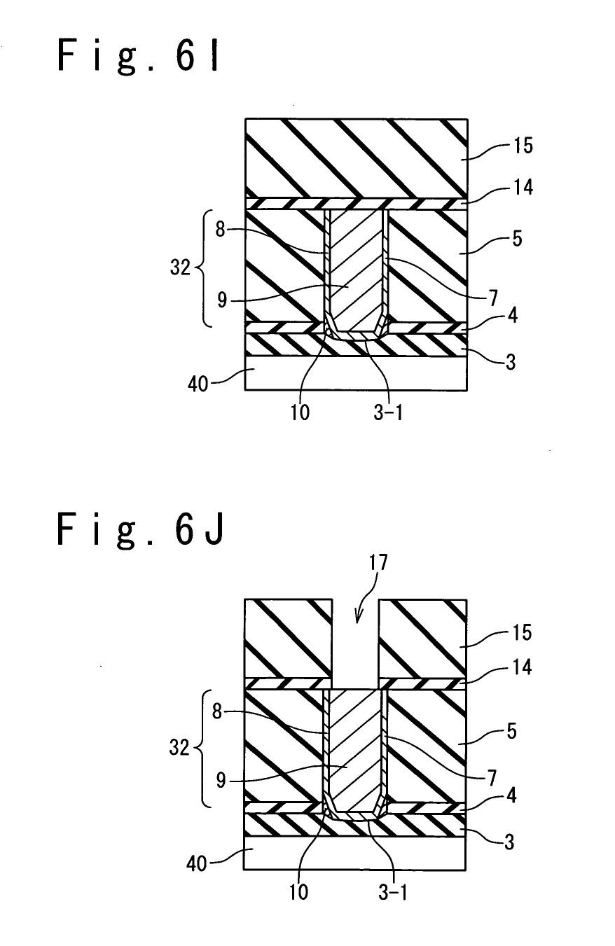

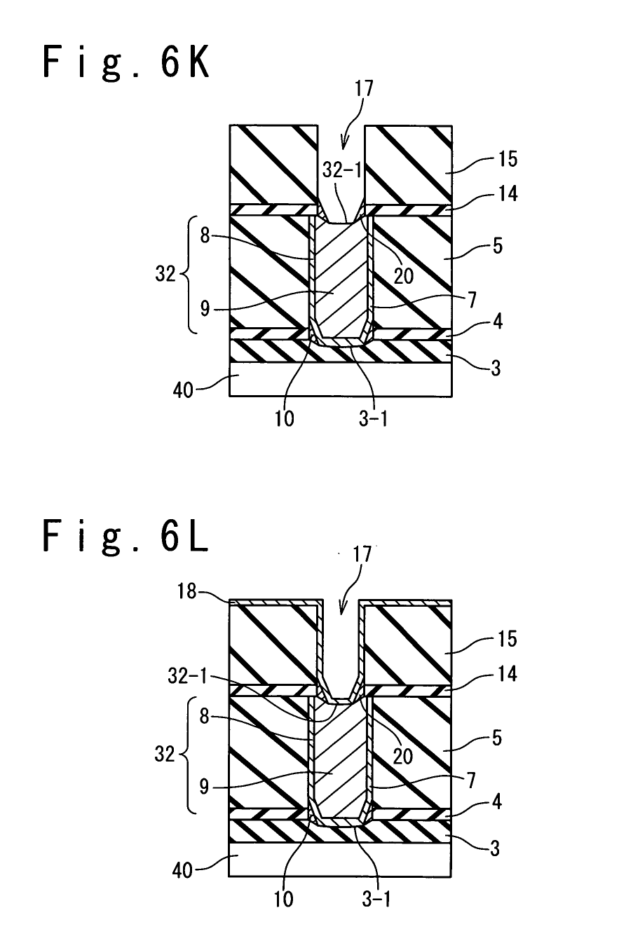

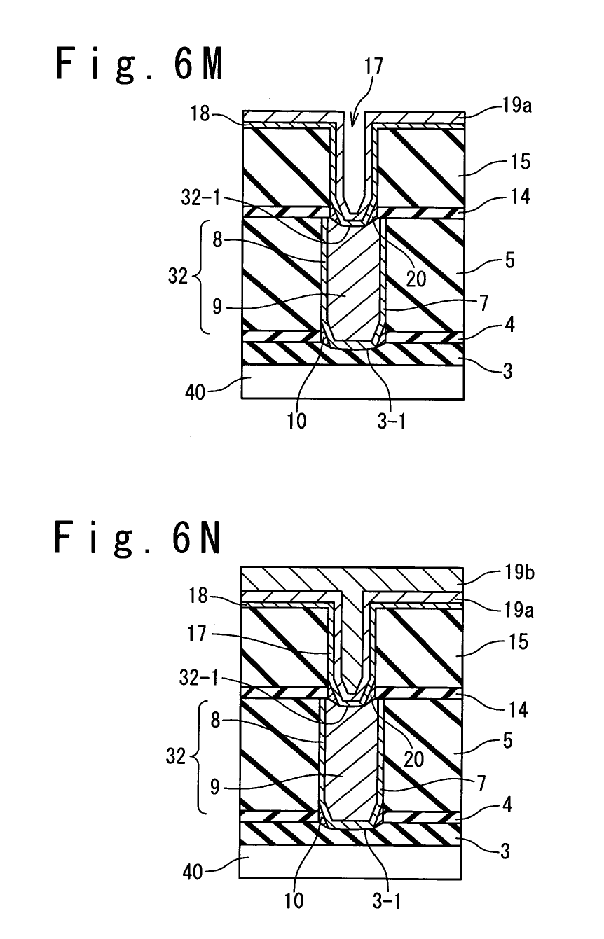

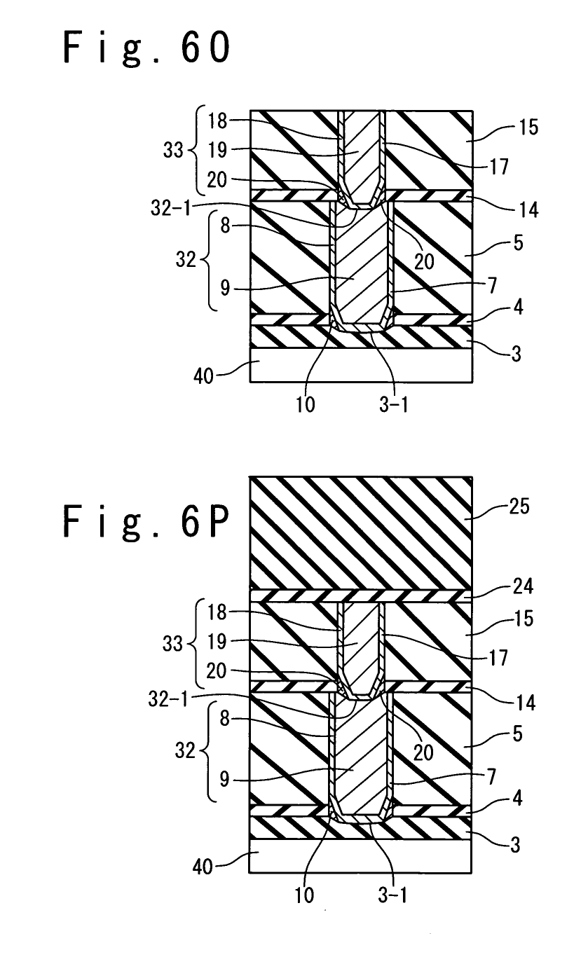

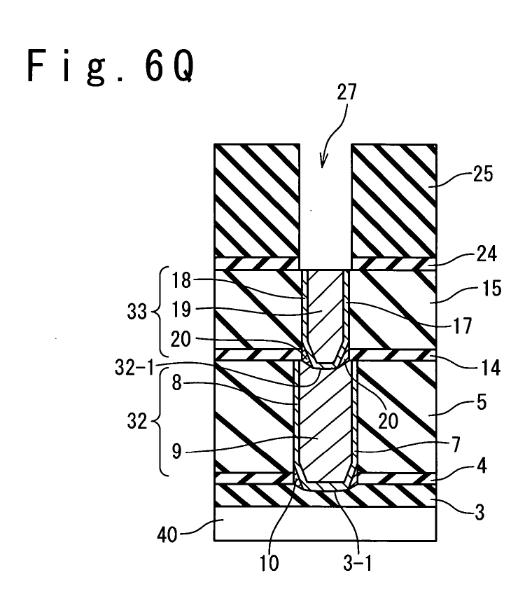

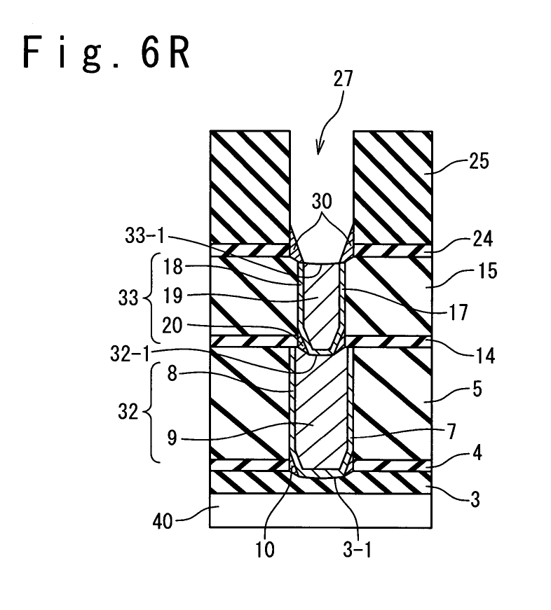

Next, the manufacturing method of the semiconductor device according to the embodiment of the present invention will be described, with reference to FIGS. 6A to 6R.

FIGS. 6A to 6R are cross sectional views showing the semiconductor device of the single damascene structure according to the embodiment of the present invention in the manufacturing method.

Referring to FIG. 6A, the stopper insulating film 4 is formed to cover the interlayer insulating film 3 on the substrate 40, and the low dielectric constant insulating film 5 is formed to cover the stopper insulating film 4. Subsequently, a photo-resist formed on the low dielectric constant insulating film 5 is exposed to have a pattern of the wiring line trench 7. Then, the photo-resist corresponding to the pattern of the wiring line trench 7 is removed. Subsequently, the low dielectric constant insulating film 5 is selectively etched to the stopper insulating film 4 and the upper portion of the wiring line trench 7 is formed. Then, the stopper insulating film 4 is etched back and the lower portion of the wiring line trench 7 is formed. At this time, in the bottom of the wiring line trench 7, a part of the upper portion of the interlayer insulating film 3 is exposed. Subsequently, a photo-resist is removed by an ashing method. Then, the wiring line trench 7 is washed with organic peeling solution. Then, the wiring line trench 7 is rinsed with non-aqueous solution. Through the above processes, the wiring line trench 7 is formed, as shown in FIG. 6B.

Next, as shown in FIG. 6C, the sputtering etching is carried out to irradiate Ar ions to the bottom of the wiring line trench 7. Thus, the upper portion of the interlayer insulating film 3 which is exposed in the bottom of the wiring line trench 7 is sputtered. The material of the sputtered interlayer insulating film 3 is deposited in the corner portions where the side walls of the wiring line trench 7 and the bottom intersect. This portion corresponds to a first taper section 10. Also, a portion of the upper portion of the interlayer insulating film 3 after etched is a contact section 3-1. At this time, the condition when the interlayer insulating film 3 is sputtered with the Ar ions is experimentally determined based on the material and size of each section of the manufactured semiconductor device. As an example, the following condition can be used. The size of the wiring line trench: opening of 0.22 μm×depth 0.4 μm

An aspect ratio: 2

a sputtering pressure: 0.3 mTorr (Ar gas)

RF power (13.56 MHz): 300 W/100 cm²

a substrate temperature (wafer temperature): below the room temperature

Next, as shown in FIG. 6D, the barrier metal film 8 of Ta/TaN is formed to cover the side walls of the wiring line trench 7 containing the surfaces of the first taper sections 10, the bottom thereof and the surface of the low dielectric constant insulating layer 5 by the sputtering method. At this time, the first taper section 10 is located in the corner portions between the side walls and the bottom in the wiring line trench 7. The corner portions are filled such that the material of the barrier metal film 8 can be easily distributed to the corner portions of the wiring line trench 7. Thus, as described in FIG. 5A, the barrier metal film 8 can be formed in the film forming difficult region. That is, it is possible to from the barrier metal film 8 in the whole wiring line trench 7. This state is shown in FIG. 6D.

Next, as shown in FIG. 6E, a seed conductor film 9a is formed to cover the barrier metal film 8. The seed conductor film 9a is a metal film formed by the sputtering method or the CVD method. The seed conductor film 9a is formed of the material of the conductor section 9. In this case, a copper (Cu) film is formed by the sputtering method. When the conductor section 9 is formed by the copper plating method to be described later, the seed conductor film 9a functions as seeds.

Next, as shown in FIG. 6F, a conductor film 9b of Cu is formed by the metal plating method to cover the seed conductor film 9b and to fill the wiring line trench 7.

Next, as shown in FIG. 6G, the barrier metal film 8, the seed conductor film 9a and the conductor film 9b are polished by the CMP method to remove unnecessary films on the wiring line trench 7. In this way, the first wiring line 32 of the barrier metal layer 8 and the conductor film 9 is formed.

Next, as shown in FIG. 6H, the stopper insulating film 14 is formed to cover the first wiring line 32 and the interlayer insulating layer 5.

Next, as shown in FIG. 6I, the interlayer insulating film 15 is formed to cover the stopper insulating film 14.

Next, as shown in FIG. 6J, the shape of the via-hole 17 is exposed by using the photo-resist formed on the interlayer insulating film 15. Then, the photo-resist corresponding to the shape of the via-hole 17 is removed. Subsequently, the interlayer insulating film 15 is selectively etched to the stopper insulating film 14 to form the upper portion of the via-hole 17. Subsequently, the photo-resist is removed by the ashing method. Then, the stopper insulating film 14 is etched back and the lower portion of the via-hole 17 is formed. At this time, a part of the upper portion of the first wiring line 32 is exposed in the bottom on the via-hole 17. After that, the via-hole 17 is washed with organic peeling solution. Then, the via-hole 17 is rinsed with non-aqueous solution. Through the above processes, the via-hole 17 is formed to have a space or hole of a cylinder shape.

Next, as shown in FIG. 6K, the sputtering etching is carried out to irradiate Ar ions to the bottom of the via-hole 17. Cu in the upper portion of the first wiring line 32 (the conductor section 9) which is exposed in the bottom of the via-hole 17 is sputtered. The whole or a part of the sputtered Cu is deposited in the corner portions where the inner wall of the via-hole 17 and the bottom thereof intersect. This portion is the second taper section 20. Also, the etched portion of the upper portion of the first wiring line 32 (the bottom of the via-hole 17) is a contact section 32-1.

The second taper section 20 is formed of the same conductor (Cu) as the first wiring line 32, and the cross section of the via-plug 33 is not reduced. Therefore, the formation of the second taper section 20 does not have an influence on the resistance value of the via-plug 33. This sputtering etching is carried out at a temperature such that the bottom of the via-hole 17 is below the room temperature. Therefore, Cu of the second taper section 20 does not aggregate. Also, this process removes an oxide film from the surface of the via-hole 17 at the same time. That is, the contact resistance between the via-plug 33 and the first wiring line 32 can be reduced. At this time, the condition when the first wiring line 32 is sputtered with Ar ions (sputtering etching) is experimentally determined based on the material and size at each section of the manufactured semiconductor device. As an example, the following condition can be used.

The size of the via-hole: opening of 0.2 μm×depth of 0.4 μm

an aspect ratio: 2.0

sputtering pressure: 0.3 mTorr (Ar gas)

RF power: 300 W/100 cm² (13.56 MHz)

wafer temperature: below the room temperature

Next, as shown in FIG. 6L, the barrier metal film 18 of Ta/TaN is formed by the sputtering method to cover the inner wall and bottom of the via-hole 17, and the surface of the interlayer insulating layer 15, containing the surface of the second taper section 20. At this time, the second taper section 20 is located on the corner portions where the inner wall of the via-hole 17 and the bottom thereof intersect. The corner portions are filled, and it is easy to distribute the material of the barrier metal film 18 into the corner portions of the via-hole 17. Then, as described above with reference to FIG. 5B, the barrier metal film 18 can be formed in the film forming difficult region. That is, the barrier metal film 18 can be formed on the whole of via-hole 17. This sputtering is carried out at a temperature such that the bottom of the via-hole 17 is below the room temperature. Therefore, Cu of the second taper section 20 does not aggregate. Also, when the barrier metal film 18 is formed once, the surface energy of Cu in the second taper section 20 can be made zero. Thus, the aggregation of Cu in the second taper section 20 can be restrained.

Next, as shown in FIG. 6M, the seed conductor film 19a is formed to cover the barrier metal film 18. The seed conductor film 19a is a metal film formed by the sputtering method or the CVD method, and is formed of the material of the conductor section 19. Here, the copper (Cu) film is formed by the sputtering method. When the conductor section 19 is formed by the copper plating method as be described later, the seed conductor film 19a functions as the seed.

Next, as shown in FIG. 6N, the conductor film 19b of Cu is formed to cover the seed conductor film 19a and to fill the via-hole 17 by the plating method. Subsequently, as shown in FIG. 60, the barrier metal film 18, the seed conductor film 19a and the conductor film 19b is removed by the CMP method to remove unnecessary films above the via-hole 17. In this way, the via-plug or via-contact 33 is formed from the second taper section 20, the barrier metal layer 18, and the conductor layer 19.

Next, as shown in FIG. 6P, the stopper insulating film 24 is formed to cover the via-plug 33 and the interlayer insulating layer 15. Moreover, the low dielectric constant insulating film 25 is formed to cover the stopper insulating film 24. Subsequently, as shown in FIG. 6Q, the shape of the wiring line trench 27 is exposed in the photo-resist formed on the low dielectric constant insulating film 25. Then, the photo-resist corresponding to the shape of the wiring line trench 27 is removed. Subsequently, the low dielectric constant insulating film 25 is selectively etched to the stopper insulating film 24 and the upper portion of the wiring line trench 27 is formed. Then, the photo-resist is removed by the ashing method. After that, the stopper insulating film 24 is etched back and the lower portion of the wiring line trench 27 is formed. At this time, a part of the surface of the interlayer insulating layer 15 and the upper portion of the via-plug 33 are exposed in the bottom of the wiring line trench 27. After that, the wiring line trench 27 is washed with organic peeling solution, and then is rinsed with non-aqueous solution. Through the above processes, the wiring line trench 27 is formed.

Next, as shown in FIG. 6R, the sputtering etching is carried out to irradiate Ar ions to the bottom of the wiring line trench 27. Thus, (1) a part of the surface of the interlayer insulating layer 15 and an upper portion of the via-plug 33 exposed in the bottom of the wiring line trench 27 are sputtered in a position where the via-plug 33 is formed. The material of the sputtered interlayer insulating layer 15 and the material of the sputtered via-plug 33 are deposited in the corner portions which the side walls of the wiring line trench 27 and the bottom thereof intersect. On the other hand, (2) a part of the surface of the interlayer insulating layer 15 exposed in the bottom of the wiring line trench 27 is sputtered in a position where the via-plug 33 is not formed. These deposited portions are third taper sections 30. Also, the etched portion of the upper portion of the via-plug 33 and the etched portion of the upper portion of the interlayer insulating layer 15 form a contact section 33-1.

The portion of the third taper sections 30 which the via-plug 33 is formed is formed of substantially the same material as the via-plug 33, i.e., conductor (Cu), and the third taper sections 30 do not decrease the cross section of the second wiring line 34. Therefore, the third taper sections 30 do not have an influence on the resistance value of the second wiring line 34. This sputtering etching is carried out at a temperature such that the bottom of the wiring line trench 27 is below the room temperature. Therefore, Cu in the third taper section 30 does not aggregate. Also, this process removes an oxide film from the surface of the wiring line trench 27 at the same time. That is, the contact resistance between the second wiring line 34 and the via-plug 33 can be reduced. At this time, the condition when the interlayer insulating layer 15 and the via-plug 33 are sputtered with Ar ions is experimentally determined based on the material and size of each section of the manufactured semiconductor device. As an example, the same condition as the case that the above-mentioned interlayer insulating film 3 is sputtered with Ar ions can be used.

Next, the barrier metal film 28 of Ta/TaN is formed by the sputtering method to cover the side walls of the wiring line trench 27, containing the surfaces of the third taper sections 30, the bottom thereof and the surface of the low dielectric constant insulating layer 25. At this time, the third taper sections 30 are located on the corner portions where the side walls of the wiring line trench 27 and the bottom intersect. The corner portions are filled, and it is possible to easily distribute the material of the barrier metal film 28 into the corner portions in the bottom of the wiring line trench 27. Thus, as described with reference to FIG. 5A, the barrier metal film 28 can be formed in the film forming difficult region. That is, the barrier metal film 28 can be formed in the whole wiring line trench 27, like the formation of the barrier metal film 8. This sputtering is carried out at a temperature such that the bottom of the wiring line trench 27 is below the room temperature. Therefore, Cu in the third taper section 30 does not aggregate. Also, when the barrier metal film 28 is formed once, the surface energy of Cu in the third taper section 30 can be made zero. Thus, the aggregation of Cu in the third taper section 30 can be restrained.

Hereinafter, like the first wiring line 32, the seed conductor film 29 which covers the barrier metal film 28, and the conductor film 29b which fills the wiring line trench 27 and covers the seed conductor film 29 are continuously formed. After that, an unnecessary portion of the barrier metal film 28, the seed conductor film 29 and the conductor film 29 above the wiring line trench 27 is removed by the CMP method. In this way, the second wiring line 34 of the barrier metal layer 28, the conductor layer 29 and the third taper section 30 is formed. Then, The state when the stopper insulating layer 36 is formed on it is shown in FIG. 3.

In this embodiment, an example will be described in which the present invention is applied to the semiconductor device which has wiring lines in two layers and a via-plug to connect them. To apply the present invention to the wiring line is due to the following reason. That is, with miniaturization of the wiring line width in the semiconductor device, an aspect ratio becomes large even in the wiring line. In this case, it is difficult to form a barrier metal layer, and as the result, a problem is caused that copper aggregates so that the wiring line is broken, like a case of the via-plug.

The present invention can be applied to a semiconductor device which has a multi-layer wiring line structure.

In the present invention, the first taper section 10 and the third taper section 30 are provided for the bottoms of the first wiring line 32 and the second wiring line 34, respectively. In the same way, the second taper section 20 is provided for the bottom of the via-hole 17. Therefore, the barrier metal film can be uniformly formed on the bottom of the wiring line and the via-hole. In addition, the barrier metal film can be surely formed in the film forming difficult region, because the barrier metal film grows from the upper and lower portion than the film forming difficult region. Therefore, the barrier metal film can be surely formed on the whole inside of the wiring line and on the via-hole.

Because the barrier metal film is substantially uniformly formed, the seed conductor film and the conductor film never directly contact the low dielectric constant insulating layer, the interlayer insulating layer, and the stopper insulating layer formed outside the wiring line and the via-hole. Therefore, the migration of the copper (Cu) and aggregation which are caused in the heat cycle in the post process can be prevented. Also, it is possible to prevent the wiring line from breaking and the reliability of the wiring line can be improved.

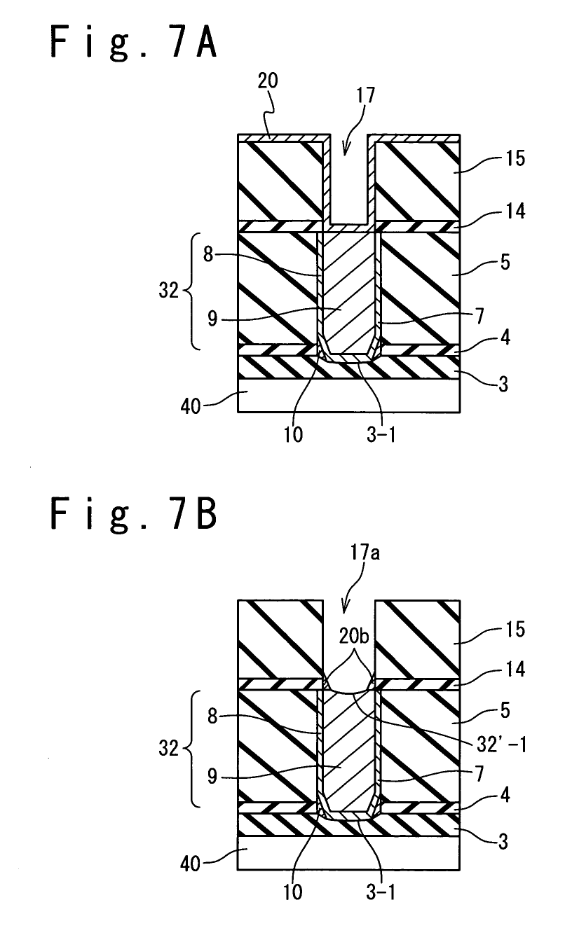

In this embodiment, the first taper section 10 to the third taper section 30 are formed by sputtering-etching the upper portion of the first wiring line 32, the via-plug 33 and the second wiring line 34. However, the respective taper sections may be formed through film forming processes. This is shown in FIGS. 7A and 7B.

FIGS. 7A and 7B are cross sectional views showing another method of forming the taper sections. Here, of the first taper section 10 to the third taper section 30, the second taper section 20 will be described as an example. As shown in FIG. 7A, a film 20 is formed of the same material as the second taper section 20 on the inner wall and bottom of the via-hole 17 and on the surface of the interlayer insulating layer 15. It is desirable that this film is thicker than the barrier metal film 18. For example, the film thickness of the film is 60 nm. In this case, the film can be substantially uniformly formed on the whole inner surface of the via-hole 17 even if there is not the second taper section 20. After that, the film 20 is etched back. By appropriately controlling the condition of the etching back, a portion of the film 20 can be left in the corner section where the bottom and the inner wall intersect in the via-hole 17. The left portion is a taper section 20b which has substantially the same shape as the second taper section 20. This is shown in FIG. 7B. This corresponds to FIG. 6K. The other processes are the same as those of the above embodiment.

In case of FIGS. 7A and 7B, the condition of the etching back is experimentally determined based on the material of the film 20 and the material and size of each section of the manufactured semiconductor device. Also, it is desirable that the material of the film 20 is metal. In this case, the cross section of the via-plug 33 does not decrease even if the taper section 20 exists. Moreover, it is desirable that the metal is used because it is easy to form more uniformly than the barrier metal film 18. When the film is formed like FIG. 7A, the corner section can be surely formed. As the metal, aluminum is exemplified. In case of aluminum, it never diffuses into the interlayer insulating layer 15 and the stopper insulating layer 14. In this case, the same effect as the semiconductor device which is manufactured in the processes of FIGS. 6A to 6R can be achieved.

Also, the material of the taper section can be selected from various kinds of material. Thus, it is possible to further improve the reliability of the taper section 20b.

According to the present invention, the barrier metal film can be surely formed in the wiring line containing a contact and it is possible to improve the reliability of the wiring line containing contact.

While various particular embodiments set forth herein have been described in detail, the present invention could be subject to various changes, substitutions, and alternations without departing from the spirit and scope of the invention. Accordingly, the present invention is intended to be limited only as defined by the appended claims.

What is claimed is:

1. A semiconductor device comprising:
a lower layer formed on a substrate;
a first insulating layer covering said lower layer;
a first concave section extending from a surface of said first insulating layer to said lower layer;
a first taper section formed along a corner portion between a bottom of said first concave section and an inner wall of said first concave section, and having a taper surface which extends toward a center of said bottom;
a first conductor section formed of material containing copper to fill said first concave section in which said first taper section is formed.

2. The semiconductor device according to claim 1, wherein said lower layer comprises:
an interlayer insulating film formed on said substrate;
a second insulating layer formed on said interlayer insulating film; and
a second conductor section formed of material containing copper in said second insulating layer at a region including a position corresponding to said first conductor section.

3. The semiconductor device according to claim 2, wherein said lower layer further comprises:
a second taper section formed along a corner portion between a bottom of a first trench and each of side walls of said first trench,
said first trench extends from a surface of said second insulating layer to said interlayer insulating film, and
said second conductor section is provided to fill said first trench.

4. The semiconductor device according to claim 3, wherein said second taper section is formed of substantively same material as said interlayer insulating film.

5. The semiconductor device according to claim 2, wherein said second conductor section extends to an inside of said interlayer insulating film.

6. The semiconductor device according to claim 2, further comprising:
a third insulating layer formed on said first insulating layer and said first conductor section; and
a third conductor section formed of material containing copper in said third insulating layer at a region including a position corresponding to said first conductor section.

7. The semiconductor device according to claim 6, further comprising:
a third taper section formed along a corner portion between a bottom of a second trench and each of side walls of said second trench,
wherein said second trench extends from a surface of said third insulating layer to said first conductor section, and
said third conductor section is provided to fill said second trench.

8. The semiconductor device according to claim 7, wherein said third taper section is formed of substantively same material as said first conductor section.

9. The semiconductor device according to claim 6, wherein said third conductor section extends to an inside of said first conductor section.

10. The semiconductor device according to claim 6, wherein said second and third conductor sections are first and second wiring lines, respectively, and
said first conductor section is as a contact plug to connect said first and second wiring lines.

11. The semiconductor device according to claim 1, wherein an aspect ratio of said first concave section is equal to or more than 2.

12. A method of manufacturing a semiconductor device comprising the steps of:
(a) forming a first concave section extending from a surface of a first insulating layer to a lower layer such that a part of a surface of said lower layer is exposed, wherein said first insulating layer is formed on said lower layer which is formed on a substrate;
(b) forming a first taper section along a corner portion between a bottom of said first concave section and an inner wall of said first concave section; and
(c) forming a first conductor section of metal containing copper by filling said first concave section in which said first taper section is formed.

13. The method of manufacturing the semiconductor device according to claim 12, wherein said (b) step comprises the step of:
sputter-etching a bottom of said first concave section such that etched material of said lower layer is deposited in said corner portion to produce said first taper section.

14. The method of manufacturing the semiconductor device according to claim 12, wherein said (b) step comprises the steps of:
forming an auxiliary film to cover said inner wall and said bottom of said first concave section, and a surface of said first insulating layer; and
etching back said auxiliary film to produce said first taper section and to remove said auxiliary film from said inner wall and said bottom of said first concave section, and the surface of said first insulating layer.

15. The method of manufacturing the semiconductor device according to claim 12, wherein said lower layer contains a second conductor section of material containing copper,
said (a) step comprises:
exposing a part of said second conductor section in said first concave section.

16. The method of manufacturing the semiconductor device according to claim 12, further comprising the step forming said lower layer,
wherein said step of forming said lower layer comprises the step of:
forming an interlayer insulating film on said substrate;
forming a second insulating layer on said interlayer insulating film; and
forming a second conductor section of material containing copper in said second insulating layer at a position corresponding to said first conductor section.

17. The method of manufacturing the semiconductor device according to claim 16, wherein said step of forming said lower layer further comprises the steps of:
forming a first trench in said second insulating layer to extend from a surface of said second insulating layer to said interlayer insulating film;
forming a second taper section along a corner portion between a bottom of said first trench and each of side walls of said first trench; and
filling said first trench with said second conductor section.

18. The method of manufacturing the semiconductor device according to claim 17, wherein said second taper section is formed of substantively same material as said interlayer insulating film.

19. The method of manufacturing the semiconductor device according to claim 16, further comprising the steps of:
forming a third insulating layer on said first insulating layer and said first conductor section;
forming a second trench in said third insulating layer to extend from a surface of said third insulating layer to said first conductor section;
forming a third taper section along a corner portion between a bottom of said second trench and each of side walls of said second trench; and
forming a third conductor section of material containing copper by filling said second trench.

20. The method of manufacturing the semiconductor device according to claim 19, wherein said step of forming said third taper section includes forming said third taper section with substantively same material as said first conductor section.

21. The method of manufacturing the semiconductor device according to claim 12, wherein said second and third conductor sections are first and second wiring lines, respectively, and
said first conductor section is as a contact plug to connect said first and second wiring lines.

22. The method of manufacturing the semiconductor device according to claim 12, wherein an aspect ratio of said first concave section is equal to or more than 2.
